(19) United States
(12) Patent Application Publication
(10) Pub. No.: US 2026/0344468 A1
(43) Pub. Date: Oct. 29, 2026

(54) INTERCONNECT SUBSTRATE AND METHOD OF MAKING THE SAME

(71) Applicant: SHINKO ELECTRIC INDUSTRIES CO., LTD., Nagano (JP)

(72) Inventor: Keigo SATO, Nagano (JP)

(21) Appl. No.: 19/646,826

(22) Filed: Apr. 14, 2026

(30) Foreign Application Priority Data
Apr. 24, 2025 (JP) 2025-072635

(51) Int. Cl. H10W 70/63; H10W 70/05; H10W 70/695; H10W 74/15; H10W 90/00

(52) U.S. Cl. CPC H10W 70/635; H10W 70/095; H10W 70/096; H10W 70/695; H10W 74/15; H10W 90/724

(57) ABSTRACT

An interconnect substrate includes a glass core layer having one surface and another surface, a first laminate including an interconnect layer and an insulating layer and disposed on the one surface of the core layer, and a resin portion, wherein the insulating layer contains a filler, and the resin portion has a filler content smaller than that of the insulating layer or does not contain a filler, wherein a first peripheral portion of the one surface of the core layer is not covered with the first laminate, wherein the resin portion covers a side surface of the core layer and a part of the first peripheral portion, the part being adjacent to the side surface of the core layer, and wherein a first end surface of the resin portion located toward the first laminate is spaced apart from a side surface of the first laminate.

### CROSS-REFERENCE TO RELATED APPLICATIONS

The present application is based on and claims priority to Japanese Patent Application No. 2025-072635 filed on Apr. 24, 2025, with the Japan Patent Office, the entire contents of which are incorporated herein by reference.

### FIELD

The disclosures herein generally relate to interconnect substrates and methods of making an interconnect substrate.

### BACKGROUND

As known in the art, interconnect substrates may have core layers and laminates including interconnect layers and insulating layers laminated on the core layers (Patent Document 1). The manufacturing process of an interconnect substrate of such a kind may include, for example, preparing a core layer having a plurality of interconnect regions for singulation into interconnect substrates and cutting regions along which cuts are to be made for singulation, and forming a laminate on the upper surface of the core layer. Thereafter, for example, separation grooves are formed in the laminate located in the cutting regions, and the core layer is cut along the widthwise centers of the bottoms of the grooves to produce singulated interconnect substrates.

A core layer made of glass may sometimes be used in an interconnect substrate. In this case, there is a possibility that the side surface of the core layer made of glass has structural defects, such as chips or cracks, after the cutting for singulation.

### Related-Art Document

### Patent Document

Patent Document 1 Japanese Laid-Open Patent Publication No. 2018-110150

### SUMMARY

According to an aspect of the embodiment, an interconnect substrate includes a core layer made of glass having one surface and another surface, a first laminate including an interconnect layer and an insulating layer and disposed on the one surface of the core layer, and a resin portion, wherein the insulating layer contains a filler, and the resin portion has a filler content smaller than that of the insulating layer or does not contain a filler, wherein a first peripheral portion of the one surface of the core layer is not covered with the first laminate, wherein the resin portion covers a side surface of the core layer and a part of the first peripheral portion, the part being adjacent to the side surface of the core layer, and wherein a first end surface of the resin portion located toward the first laminate is spaced apart from a side surface of the first laminate.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a plan view illustrating an example of an interconnect substrate according to a first embodiment;

FIG. 2A and 2B are cross-sectional views illustrating the example of the interconnect substrate according to the first embodiment;

FIG. 3 is a drawing illustrating an example of a manufacturing process of the interconnect substrate according to the first embodiment;

FIGS. 4A through 4D are drawings illustrating the example of the manufacturing process of the interconnect substrate according to the first embodiment;

FIGS. 5A through 5C are drawings illustrating the example of the manufacturing process of the interconnect substrate according to the first embodiment;

FIG. 6 is a drawing illustrating the example of the manufacturing process of the interconnect substrate according to the first embodiment;

FIGS. 7A through 7C are drawings illustrating the example of the manufacturing process of the interconnect substrate according to the first embodiment; and

FIG. 8 is a cross-sectional view illustrating an example of a semiconductor device according to the second embodiment.

### DESCRIPTION OF EMBODIMENTS

Embodiments of the invention will be described below with reference to the accompanying drawings. In these drawings, the same components are denoted by the same reference numerals, and duplicate descriptions may be omitted.

### FIRST EMBODIMENT

### Structure of Interconnect Substrate

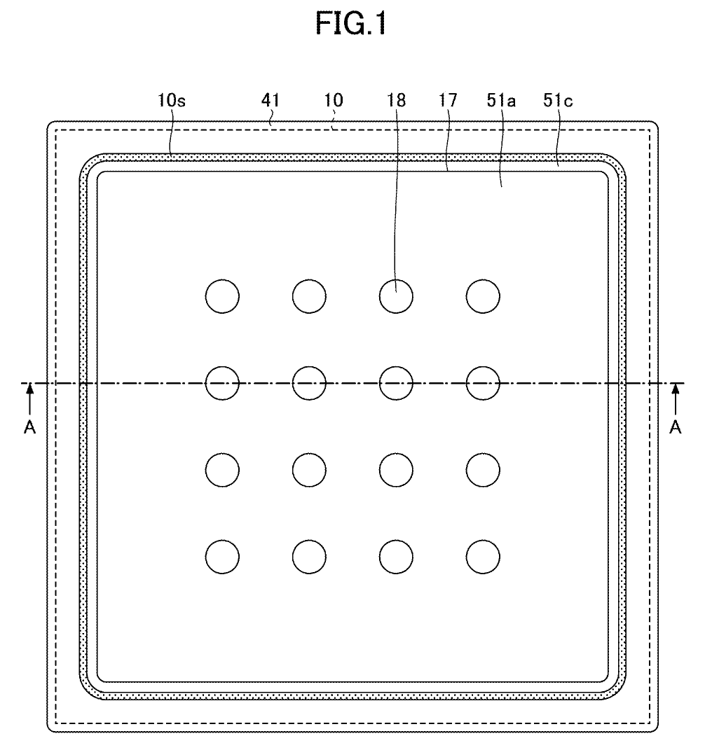

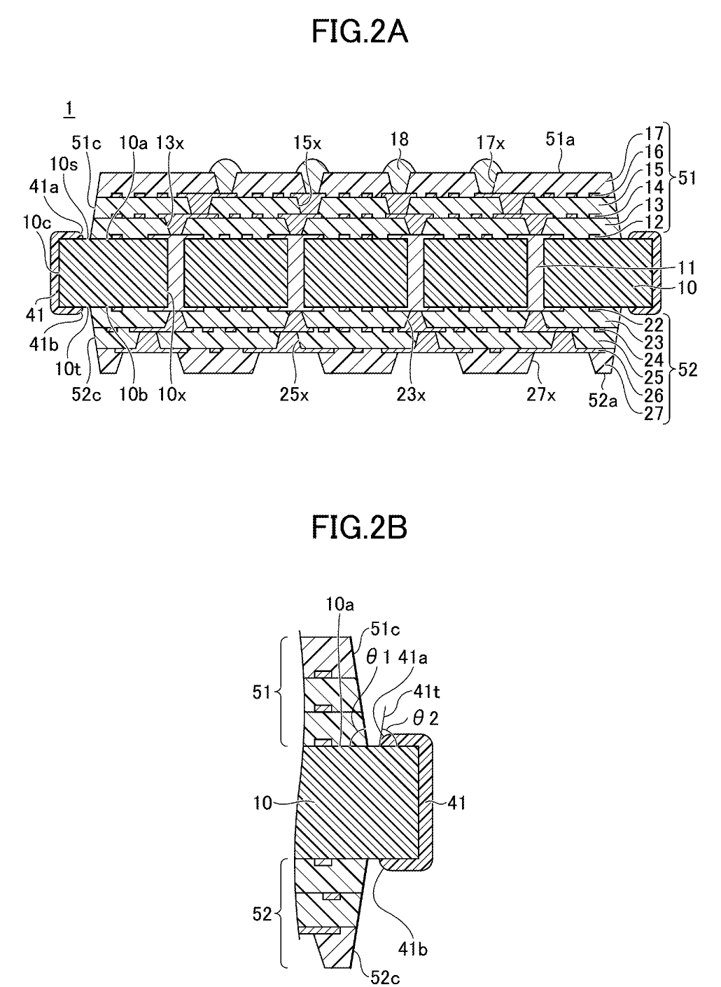

FIG. 1 is a plan view illustrating an example of an interconnect substrate according to a first embodiment. FIGS. 2A and 2B are cross-sectional views illustrating the example of the interconnect substrate according to the first embodiment, and FIG. 2A is a cross-sectional view taken along line A-A in FIG. 1. FIG. 2B is a partial enlarged view of the right end portion of the structure shown in FIG. 2A.

Referring to FIGS. 1 and 2A and 2B , an interconnect substrate 1 includes a core layer 10 having a first surface 10a and a second surface 10b opposite the first surface 10a, a first laminate 51 including interconnect layers and insulating layers disposed on the first surface 10a of the core layer 10, a second laminate 52 including interconnect layers and insulating layers disposed on the second surface 10b of the core layer 10, and a resin portion 41. The interconnect substrate 1 may have external connection terminals 18. The interconnect substrate 1 may be formed to have a rectangular shape in plan view, for example.

The first laminate 51 includes an interconnect layer 12, an insulating layer 13, an interconnect layer 14, an insulating layer 15, an interconnect layer 16, and a solder resist layer 17 sequentially laminated on the first surface 10a of the core layer 10. The second laminate 52 includes an interconnect layer 22, an insulating layer 23, an interconnect layer 24, an insulating layer 25, an interconnect layer 26, and a solder resist layer 27 sequentially laminated on the second surface 10b of the core layer 10. The first laminate 51 may be formed to have a rectangular shape in plan view, for example. Each corner of the first laminate 51 may be formed as a curved surface, for example. The second laminate 52 may be formed to have a rectangular shape in plan view, for example. Each corner of the second laminate 52 may be formed as a curved surface, for example.

In the first embodiment, for convenience, the solder resist layer 17 side of the interconnect substrate 1 is referred to as an upper side or a first side, and the solder resist layer 27 side is referred to as a lower side or a second side. The surface of a portion oriented in the same direction as the solder resist layer 17 side is referred to as a first surface or an upper surface, and the surface of a portion oriented in the same direction as the solder resist layer 27 side is referred to as a second surface or a lower surface. However, the interconnect substrate 1 may be positioned upside down when used, or may be arranged at any angle. The plan view refers to the view of an object as seen from the direction normal to the first surface 10a of the core layer 10, and the plan shape refers to the shape of an object as seen from the direction normal to the first surface 10a of the core layer 10.

The core layer 10 may be formed to have a rectangular shape in plan view, for example. The core layer 10 is made of glass. Although the kind of glass constituting the core layer 10 is not limited, alkali-free glass, quartz glass, borosilicate glass, or the like may be used, for example. The thickness of the core layer 10 is, for example, in the range of approximately 100 to 1000 μm. The core layer 10 has through holes 10x that extend through the core layer 10 in the thickness direction. The plan shape of each of the through holes 10x is, for example, circular. The diameter of each of the through holes 10x may be, for example, from 100 μm to 500 μm.

A first peripheral portion 10s of the first surface 10a of the core layer 10 is not covered with the first laminate 51. The first peripheral portion 10s is positioned on the outer side of the first laminate 51 in plan view and has a closed-loop shape. The width of the first peripheral portion 10s may be, for example, from 50 μm to 300 μm.

A side surface 51c of the first laminate 51 is constituted by the side surface of the insulating layer 13, the side surface of the insulating layer 15, and the side surface of the solder resist layer 17. The side surface 51c of the first laminate 51 is inclined inward toward the solder resist layer 17, in the direction away from the side surface 10c of the core layer 10, in cross-sectional view, for example. Alternatively, the side surface 51c of the first laminate 51 may be perpendicular to the first surface 10a of the core layer 10.

A second peripheral portion 10t of the second surface 10b of the core layer 10 is not covered with the second laminate 52. The second peripheral portion 10t is positioned on the outer side of the second laminate 52 in plan view and has a closed-loop shape. The width of the second peripheral portion 10t may be, for example, from 50 μm to 300 μm.

A side surface 52c of the second laminate 52 is constituted by the side surface of the insulating layer 23, the side surface of the insulating layer 25, and the side surface of the solder resist layer 27. The side surface 52c of the second laminate 52 is inclined inward toward the solder resist layer 27, in the direction away from the side surface 10c of the core layer 10, in cross-sectional view, for example. Alternatively, the side surface 52c of the second laminate 52 may be perpendicular to the second surface 10b of the core layer 10.

The resin portion 41 continuously and seamlessly covers the side surface 10c of the core layer 10, the part of the first peripheral portion 10s adjacent to the side surface 10c of the core layer 10, and the part of the second peripheral portion 10t adjacent to the side surface 10c of the core layer 10. The resin portion 41 may be formed in a closed-loop shape so as to surround the first laminate 51 and the second laminate 52 in plan view.

The resin portion 41 is not in contact with the side surface 51c of the first laminate 51 or the side surface 52c of the second laminate 52. That is, a first end surface 41a of the resin portion 41 is spaced apart from the side surface 51c of the first laminate 51, and a second end surface 41b of the resin portion 41 is spaced apart from the side surface 52c of the second laminate 52. For example, in plan view, the inner peripheral area of the first peripheral portion 10s is exposed in a frame shape between the first laminate 51 and the resin portion 41. In plan view, the inner peripheral area of the second peripheral portion 10t is exposed in a frame shape between the second laminate 52 and the resin portion 41. The width of the first peripheral portion 10s exposed between the first laminate 51 and the resin portion 41 and the width of the second peripheral portion 10t exposed between the second laminate 52 and the resin portion 41 may be, for example, greater than 0 μm and at most 50 μm.

The thickness of the resin portion 41 is, for example, from 10 μm to 200 μm. The thickness of the resin portion 41 covering the first peripheral portion 10s, the thickness of the resin portion 41 covering the side surface 10c of the core layer 10, and the thickness of the resin portion 41 covering the second peripheral portion 10t may be approximately constant. The thickness of each portion of the resin portion 41 is defined by the thickness in the direction perpendicular to the surface covered by the resin portion 41. The elastic modulus of the resin portion 41 is preferably from 2 GPa to 15 GPa. When the elastic modulus of the resin portion 41 is within this range, the resin portion 41 may expand and contract to some extent when heated, and thus the resin portion 41 is less likely to crack.

The resin portion 41 contains a thermosetting resin or a thermoplastic resin. Examples of the thermosetting resin include an insulating resin mainly composed of an epoxy-based resin, a polyimide-based resin, a phenol-based resin, a novolac-based resin, or the like. Examples of the thermoplastic resin include an insulating resin mainly composed of a urethane-based resin, an olefin-based resin, or the like. Being softer and more stretchable than the thermosetting resin, the thermoplastic resin provides good adhesion to the core layer 10. Further, compared with the thermosetting resin, the thermoplastic resin is easier to secure a stable film thickness at the corners or the like of the core layer 10.

The resin portion 41 may contain a filler for adjusting physical properties or the like. However, in this case, the filler content of the resin portion 41 is preferably smaller than the filler content of the insulating layer 13 or the like. Since the filler does not have tackiness, an increase in the content of the filler in the resin portion 41 reduces the adhesiveness to the core layer 10. In other words, by making the content of the filler in the resin portion 41 smaller than the content of the filler in the insulating layer 13 and the like, the adhesiveness between the resin portion 41 and the core layer 10 is effectively improved. Further, by making the content of the filler in the resin portion 41 smaller than the content of the filler in the insulating layer 13 and the like, the generation of particles due to the disengagement of the filler is effectively suppressed. Alternatively, the resin portion 41 may not contain any filler. In this case, the adhesiveness between the resin portion 41 and the core layer 10 may be further improved. Further, the generation of particles due to the disengagement of the filler may be further suppressed.

As illustrated in FIG. 2B, the side surface 51c of the first laminate 51 and the first end surface 41a of the resin portion 41 are inclined at an oblique angle relative to the first surface 10a of the core layer 10, for example. The side surface 51c of the first laminate 51 and the first end surface 41a of the resin portion 41 are inclined in directions such that the gap between them increases with the distance from the first surface 10a of the core layer 10, for example. In a cross-sectional view, the inclination angle θ1 of the side surface 51c of the first laminate 51 with respect to the first surface 10a of the core layer 10 and the inclination angle θ2 of the first end surface 41a of the resin portion 41 with respect to the first surface 10a of the core layer 10 are both acute angles. The inclination angles θ1 and θ2 are, for example, each at least 45° and less than 90°.

In a cross- sectional view, the first end surface 41a of the resin portion 41 may be entirely straight or may include a curved line. When the first end surface 41a of the resin portion 41 includes a curved line in a cross-sectional view, the angle formed between the first surface 10a of the core layer 10 and the tangent 41t at the intersection between the first end surface 41a of the resin portion 41 and the first surface 10a of the core layer 10 in the cross-sectional view is defined as the inclination angle θ2.

The side surface 52c of the second laminate 52 and the second end surface 41b of the resin portion 41 are each inclined at an oblique angle relative to the second surface 10b of the core layer 10, for example. The side surface 52c of the second laminate 52 and the second end surface 41b of the resin portion 41 are inclined in directions such that the gap between them increases with the distance from the second surface 10b of the core layer 10, for example. In a cross-sectional view, the inclination angle of the side surface 52c of the second laminate 52 with respect to the second surface 10b of the core layer 10 is approximately equal to the inclination angle θ1, and the inclination angle of the second end surface 41b of the resin portion 41 with respect to the second surface 10b of the core layer 10 is approximately equal to the inclination angle θ2.

With this arrangement, the inclination angle of the first end surface 41a of the resin portion 41 with respect to the first surface 10a of the core layer 10 is acute, which enables the reduction of the stress applied around the first end surface 41a of the resin portion 41. Further, the inclination angle of the second end surface 41b of the resin portion 41 with respect to the second surface 10b of the core layer 10 is acute, which enables the reduction of the stress applied around the second end surface 41b of the resin portion 41.

The interconnect layer 12 is disposed on the first surface 10a of the core layer 10. The interconnect layer 22 is disposed on the second surface 10b of the core layer 10. The interconnect layer 12 and the interconnect layer 22 are electrically connected to each other by through interconnects 11 formed in the through holes 10x. Each of the interconnect layers 12 and 22 is patterned in a predetermined plan shape. The interconnect layers 12 and 22 and the through interconnects 11 may be made of, for example, copper (Cu). The thicknesses of the interconnect layers 12 and 22 are, for example, in the range of approximately 10 to 40 μm. The interconnect layer 12, the interconnect layer 22, and the through interconnects 11 may be seamlessly formed.

The insulating layer 13 is an interlayer insulating layer disposed on the first surface 10a of the core layer 10 and covering the interconnect layer 12. The insulating layer 13 contains, for example, a thermosetting resin. Specifically, the material of the insulating layer 13 may be, for example, a thermosetting insulating resin or the like mainly composed of an epoxy-based resin or a polyimide-based resin. The thickness of the insulating layer 13 may be, for example, in the range of approximately 30 to 40 μm. The insulating layer 13 contains a filler such as silica (SiO₂).

Via holes 13x are formed in the insulating layer 13 to extend through the insulating layer 13 and reach the upper surface of the interconnect layer 12. The via holes 13x may each be an inverted truncated conical hole in which the diameter of the opening toward the insulating layer 15 is larger than the diameter of the opening at the upper surface of the interconnect layer 12.

The interconnect layer 14 is formed on the first side of the insulating layer 13. The interconnect layer 14 includes via interconnects filling the via holes 13x and an interconnect pattern formed on the upper surface of the insulating layer 13. The interconnect pattern is electrically connected to the interconnect layer 12 via the via interconnects. The material of the interconnect layer 14 and the thickness of the interconnect pattern may be substantially the same as those of the interconnect layer 12, for example.

The insulating layer 15 is formed on the upper surface of the insulating layer 13 so as to cover the interconnect layer 14. The material and the thickness of the insulating layer 15 may be substantially the same as those of the insulating layer 13, for example. The insulating layer 15 contains a filler such as silica (SiO₂).

Via holes 15x are formed in the insulating layer 15 to extend through the insulating layer 15 and reach the upper surface of the interconnect layer 14. The via holes 15x may each be an inverted truncated conical hole in which the diameter of the opening toward the solder resist layer 17 is larger than the diameter of the opening at the upper surface of the interconnect layer 14.

The interconnect layer 16 is formed on the first side of the insulating layer 15. The interconnect layer 16 includes via interconnects filling the via holes 15x and pads formed on the upper surface of the insulating layer 15. The pads are electrically connected to the interconnect layer 14 through the via interconnects. The material of the interconnect layer 16 and the thickness of the pads may be substantially the same as those of the interconnect layer 12, for example. The thickness of the pads may be larger than that of the interconnect layer 12. The interconnect layer 16 may also include an interconnect pattern in addition to the pads.

The solder resist layer 17 is an outermost insulating layer of the first laminate 51, and is formed on the upper surface of the insulating layer 15 so as to cover the interconnect layer 16. The solder resist layer 17 may be formed of, for example, a photosensitive epoxy-based insulating resin or acrylic-based insulating resin. The thickness of the solder resist layer 17 is, for example, in the range of approximately 15 to 35 μm.

The solder resist layer 17 has openings 17x, and portions of the upper surface of the interconnect layer 16 are located within the openings 17x. The plan shape of each of the openings 17x may be, for example, circular. The interconnect layer 16 exposed in the openings 17x may be used as pads for electrical connections to a semiconductor chip, for example. That is, the first surface 51a of the first laminate 51 of the interconnect substrate 1 is a chip mounting surface on which a semiconductor chip is to be mounted.

On the surface of the interconnect layer 16 located within the openings 17x, a metal layer may be formed, or an organic coating may be formed by applying an antioxidant treatment such as organic solderability preservative (OSP) treatment. Examples of the metal layer include an Au layer, a Ni/Au layer (a metal layer formed by laminating a Ni layer and an Au layer in this order), a Ni/Pd/Au layer (a metal layer formed by laminating a Ni layer, a Pd layer, and an Au layer in this order), and a Sn layer.

According to need, the external connection terminals 18 may be provided on the interconnect layer 16 exposed in the openings 17x. The external connection terminals 18 are, for example, solder bumps. The material of the solder bumps may be, for example, an alloy containing Pb, an alloy of Sn and Cu, an alloy of Sn and Ag, an alloy of Sn, Ag and Cu, or the like.

The insulating layer 23 is an interlayer insulating layer disposed on the second surface 10b of the core layer 10 and covering the interconnect layer 22. The material and the thickness of the insulating layer 23 may be substantially the same as those of the insulating layer 13, for example. The insulating layer 23 contains a filler such as silica (SiO₂).

Via holes 23x are formed in the insulating layer 23 to extend through the insulating layer 23 and reach the lower surface of the interconnect layer 22. The via holes 23x may each be a truncated conical hole in which the diameter of the opening toward the insulating layer 25 is larger than the diameter of the opening at the lower surface of the interconnect layer 22.

The interconnect layer 24 is formed on the second side of the insulating layer 23. The interconnect layer 24 includes via interconnects filling the via holes 23x and an interconnect pattern formed on the lower surface of the insulating layer 23. The interconnect pattern is electrically connected to the interconnect layer 22 through the via interconnects. The material and thickness of the interconnect layer 24 may be substantially the same as those of the interconnect layer 12, for example.

The insulating layer 25 is formed so as to cover the interconnect layer 24 on the lower surface of the insulating layer 23. The material and thickness of the insulating layer 25 may be substantially the same as those of the insulating layer 13, for example. The insulating layer 25 contains a filler such as silica (SiO₂).

Via holes 25x are formed in the insulating layer 25 to extend through the insulating layer 25 and reach the lower surface of the interconnect layer 24. The via holes 25x may each be a truncated conical hole in which the diameter of the opening toward the solder resist layer 27 is larger than the diameter of the opening at the lower surface of the interconnect layer 24.

The interconnect layer 26 is formed on the second side of the insulating layer 25. The interconnect layer 26 includes via interconnects filling the via holes 25x and an interconnect pattern formed on the lower surface of the insulating layer 25. The interconnect pattern is electrically connected to the interconnect layer 24 through the via interconnects. The material and the thickness of the interconnect layer 26 may be substantially the same as those of the interconnect layer 12, for example.

The solder resist layer 27 is an outermost insulating layer of the second laminate 52, and is formed on the lower surface of the insulating layer 25 so as to cover the interconnect layer 26. The material and thickness of the solder resist layer 27 may be substantially the same as those of the solder resist layer 17, for example. The solder resist layer 27 has openings 27x, and portions of the lower surface of the interconnect layer 26 are exposed within the openings 27x. The plan shape of each of the openings 27x may be, for example, circular. The interconnect layer 26 exposed in the openings 27x may be used as pads for electrical connections to a mounting substrate such as a motherboard. If necessary, a metal layer of the kind previously described may be formed on the lower surface of the interconnect layer 26 exposed in the openings 27x, or an oxidation prevention treatment such as OSP treatment may be applied.

As described heretofore, the side surfaces 10c of the core layer 10 of the interconnect substrate 1 are covered with the resin portion 41. This arrangement effectively reduces the breakage, such as chipping or cracking, of the side surfaces 10c of the core layer 10. The resin portion 41 extends from the side surfaces 10c of the core layer 10 to cover the part of the first peripheral portion 10s adjacent to the side surfaces 10c of the core layer 10 and the part of the second peripheral portion 10t adjacent to the side surfaces 10c of the core layer 10. With this arrangement, breakage such as chipping or cracking is effectively suppressed in the first peripheral portion 10s and the second peripheral portion 10t of the core layer 10.

Further, the resin portion 41 covers, in addition to the side surfaces 10c of the core layer 10, the part of the first peripheral portion 10s adjacent to the side surfaces 10c of the core layer 10 and the part of the second peripheral portion 10t adjacent to the side surfaces 10c of the core layer 10, thereby increasing the rigidity of the interconnect substrate 1.

Further, due to the reflow soldering or the like of the interconnect substrate 1, the insulating layers of the first laminate 51 and the second laminate 52 are thermally contracted. During this process, if the resin portion 41 were in contact with the side surface 51c of the first laminate 51 and/or the side surface 52c of the second laminate 52, there would be a risk of generating cracks in the resin portion 41 due to the thermal contraction of the insulating layers. For example, the expansion of the resin portion 41 would fail to conform to the contraction of the insulating layers, which results in cracks being generated around the interface between the insulating layers and the resin portion 41. However, the interconnect substrate 1 is configured such that the first end surface 41a of the resin portion 41 is spaced apart from the side surface 51c of the first laminate 51, and the second end surface 41b of the resin portion 41 is spaced apart from the side surface 52c of the second laminate 52. This arrangement causes the resin portion 41 to be less susceptible to the thermal contraction of the insulating layers, thereby effectively reducing the risk of generating cracks in the resin portion 41.

### Method of Making Interconnect Substrate

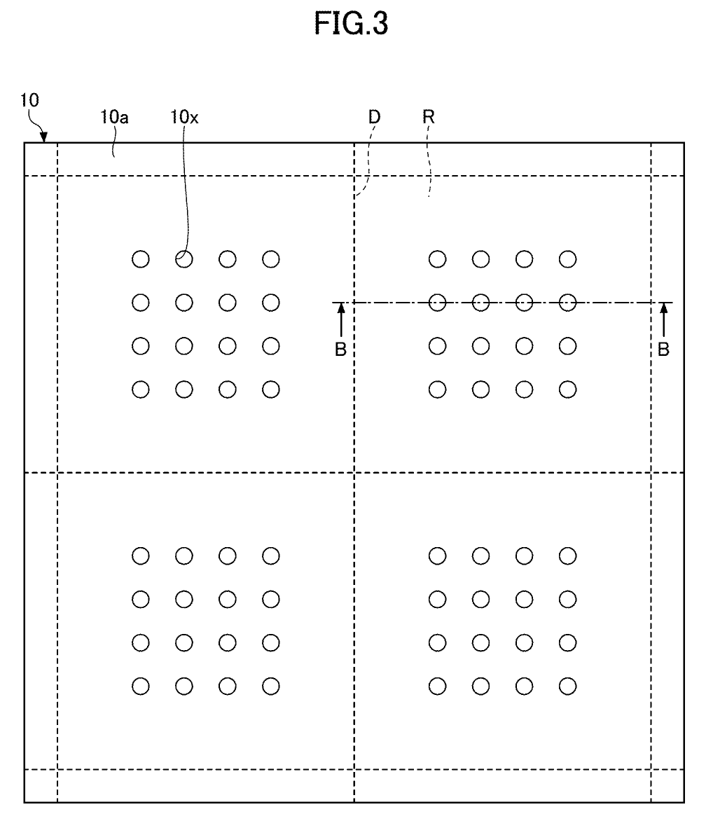

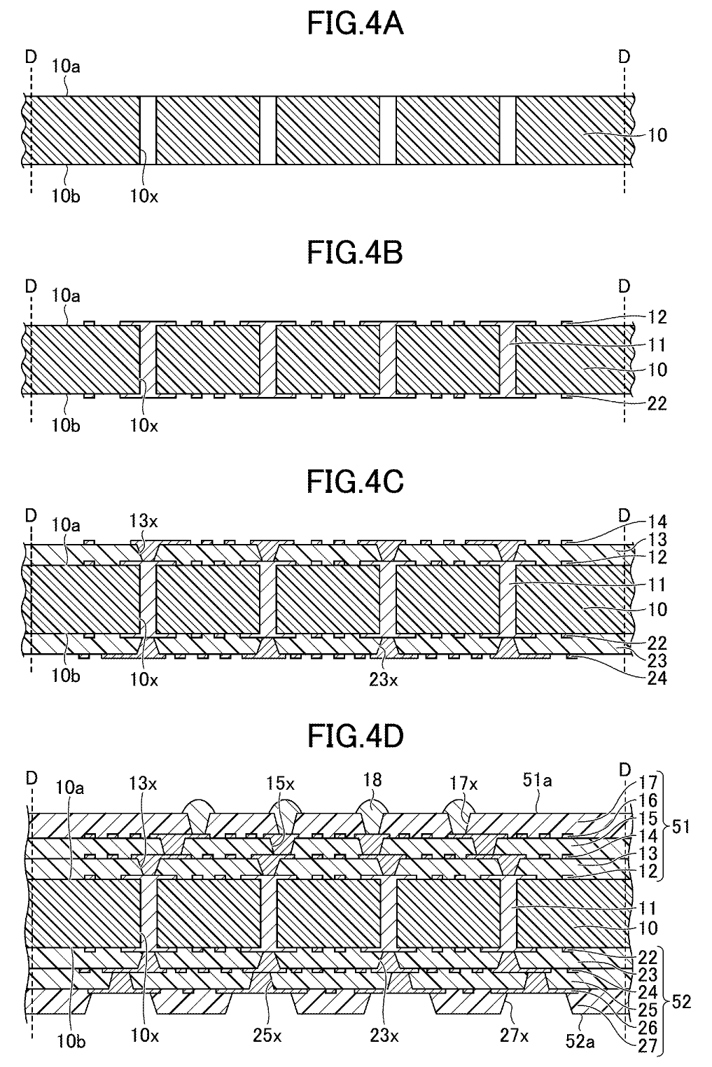

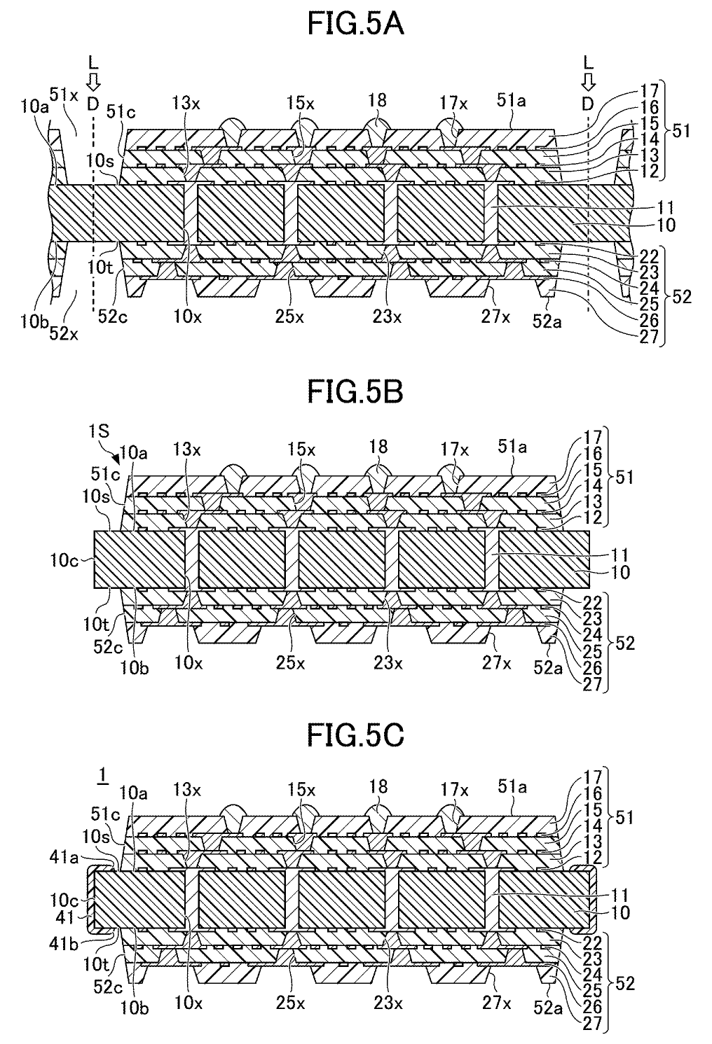

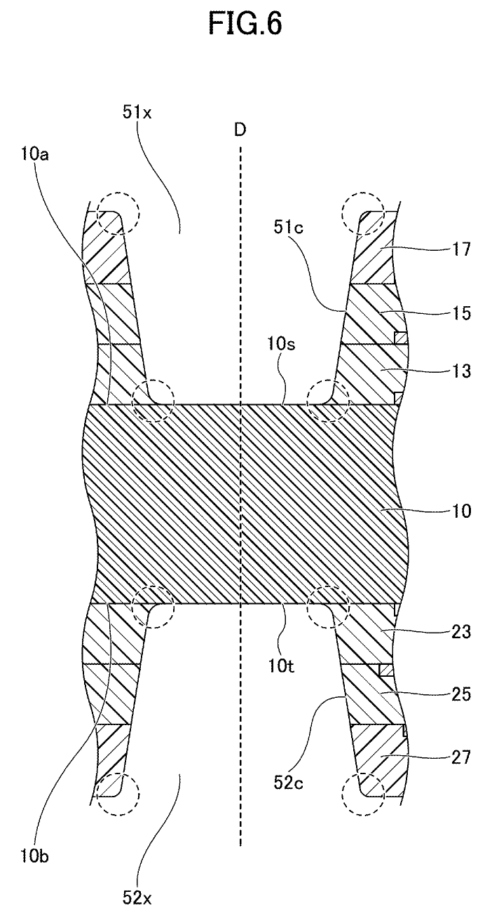

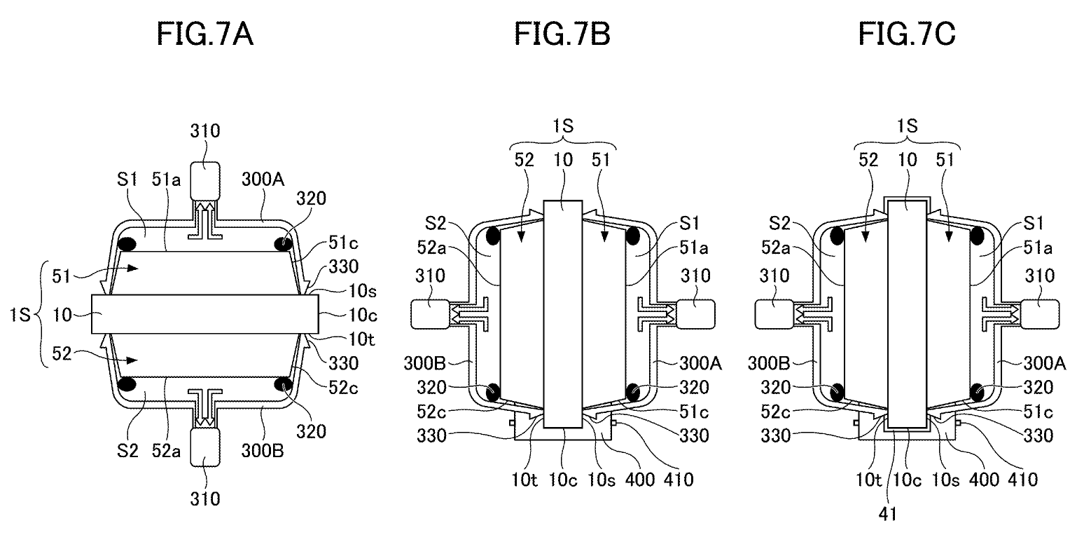

FIGS. 3 through 7A-7C are drawings illustrating an example of a manufacturing process of the interconnect substrate according to the first embodiment. FIG. 3 is a plan view, and FIGS. 4A - 4D and 5A-5C are partial cross-sectional views corresponding to the position of line B-B in FIG. 3. FIG. 6 is a partially enlarged view of a cutting region D in FIG. 5A and its vicinity. FIGS. 7A through 7C are schematic drawings illustrating an example of a preferred method of forming the resin portion.

First, in the step illustrated in FIGS. 3 and 4A, a core layer 10 made of glass is prepared. The core layer 10 includes a plurality of interconnect regions R for singulation into interconnect substrates, and cutting regions D along which cuts are to be made for singulation. Although the cutting regions D are illustrated by lines in FIGS. 3 and 4A, they may each be a region having a constant width. Next, through holes 10x extending from the first surface 10a to the second surface 10b are formed in the core layer 10 inside each interconnect region R.

The through holes 10x may be formed by wet etching, for example. Examples of the etching solution used in this process include hydrofluoric acid, strong alkali solution, and the like. If the through holes 10x were formed by drilling, there would be a risk of cracking in the glass of the core layer 10. However, the use of wet etching enables the formation of the through holes 10x without causing cracks in the glass.

In steps illustrated in FIGS. 4B through 4D, a first laminate 51 including alternately laminated interconnect layers and insulating layers is formed on the first surface 10a of the core layer 10. Further, a second laminate 52 including alternately laminated interconnect layers and insulating layers is formed on the second surface 10b of the core layer 10. An insulating resin containing a filler is used for each insulating layer of the first laminate 51 and the second laminate 52. Specifically, as illustrated in FIG. 4B, an interconnect layer 12 is formed in each interconnect region R on the first surface 10a of the core layer 10, and an interconnect layer 22 is formed in each interconnect region R on the second surface of the core layer 10, with through interconnects 11 formed in the through holes 10x. For example, a seed layer (copper or the like) covering the first surface 10a and the second surface 10b of the core layer 10 and the inner wall surfaces of the through holes 10x is formed by an electroless plating method, a sputtering method, or the like, and an electroplating layer (copper or the like) is formed on the seed layer by an electroplating method using the seed layer as a current supply path. This arrangement fills the through holes 10x with the electrolytic plating layer formed on the seed layer, and forms a conductive layer as a laminate of the seed layer and the electrolytic plating layer on each of the first surface 10a and the second surface 10b of the core layer 10. Thereafter, the conductor layers are patterned into predetermined plan shapes by a subtractive method or the like to form the interconnect layers 12 and 22 and the through interconnects 11.

As illustrated in FIG. 4C, insulating layers 13 and 23 and interconnect layers 14 and 24 are formed. First, the insulating layer 13 covering the upper surface of the interconnect layer 12 is disposed in each interconnect region R and each cutting region D on the first surface 10a of the core layer 10. Specifically, for example, a semi-cured epoxy-based resin film or the like is laminated on the first surface 10a of the core layer 10 so as to cover the interconnect layer 12, and then cured to form the insulating layer 13. Alternatively, instead of laminating epoxy-based resin film or the like, epoxy-based resin or the like in liquid or paste form may be applied and then cured to form the insulating layer 13. The material and the thickness of the insulating layer 13 are as previously described. Similarly, the insulating layer 23 covering the lower surface of the interconnect layer 22 is disposed in each interconnect region R and each cutting region D on the second surface 10b of the core layer 10.

Next, via holes 13x are formed in the insulating layer 13 to penetrate the insulating layer 13 and expose the upper surface of the interconnect layer 12. Further, via holes 23x are formed in the insulating layer 23 to penetrate the insulating layer 23 and expose the lower surface of the interconnect layer 22. The via holes 13x and 23x may be formed, for example, by laser processing using a CO₂ laser or the like. After the via holes 13x and 23x are formed, desmearing is preferably performed to remove resin residues adhering to the surfaces of the interconnect layers 12 and 22 exposed at the end of the via holes 13x and 23x.

The interconnect layer 14 is then formed on the first side of the insulating layer 13. The interconnect layer 14 includes via interconnects filling the via holes 13x and an interconnect pattern formed on the upper surface of the insulating layer 13. The interconnect layer 14 is electrically connected to the interconnect layer 12 exposed at the bottom of the via hole 13x. Similarly, an interconnect layer 24 is formed on the second side of the insulating layer 23. The interconnect layer 24 includes via interconnects filling the via holes 23x and an interconnect pattern formed on the lower surface of the insulating layer 23. The interconnect layer 24 is electrically connected to the interconnect layer 22 exposed at the end of the via holes 23x. The materials of the interconnect layers 14 and 24 and the thicknesses of the interconnect patterns may be substantially the same as those of the interconnect layer 12, for example. The interconnect layers 14 and 24 are formed, for example, by a semi-additive method.

As illustrated in FIG. 4D, insulating layers 15 and 25, interconnect layers 16 and 26, solder resist layers 17 and 27, and external connection terminals 18 are formed. First, substantially the same steps as those of FIG. 4C are repeated to form the insulating layers 15 and 25 and the interconnect layers 16 and 26. Next, the solder resist layer 17 is formed on the upper surface of the insulating layer 15 so as to cover the interconnect layer 16. Further, the solder resist layer 27 is formed on the lower surface of the insulating layer 25 so as to cover the interconnect layer 26. The solder resist layer 17 may be formed, for example, by applying a photosensitive epoxy-based insulating resin in liquid or paste form to the upper surface of the insulating layer 15 so as to cover the interconnect layer 16 by screen printing, roll coating, spin coating, or the like. Alternatively, a photosensitive epoxy-based insulating resin film, for example, may be laminated on the upper surface of the insulating layer 15 so as to cover the interconnect layer 16. The method of forming the solder resist layer 27 is substantially the same as that of the solder resist layer 17. Thereafter, the solder resist layers 17 and 27 are exposed and developed. As a result, openings 17x are formed through the solder resist layer 17 to expose the interconnect layer 16. Also, openings 27x for exposing portions of the lower surface of the interconnect layer 26 are formed in the solder resist layer 27. According to need, the external connection terminals 18 may be provided on the interconnect layer 16 exposed in the openings 17x. The external connection terminals 18 are, for example, solder bumps formed by solder reflow or the like.

In the step illustrated in FIG. 5A, first grooves 51x, each straddling a corresponding cutting region D, are formed so as to penetrate the first laminate 51 and expose the first surface 10a of the core layer 10. The first grooves 51x are formed along the cutting regions D and throughout the cutting regions D. In each interconnect region R, the first surface 10a of the core layer 10 exposed in the first grooves 51x is the portion that becomes the first peripheral portion 10s after singulation. Further, second grooves 52x, each straddling a corresponding cutting region D, are formed so as to penetrate the second laminate 52 and expose the second surface 10b of the core layer 10. The second grooves 52x are formed along the cutting regions D and throughout the cutting regions D. In each interconnect region R, the second surface 10b of the core layer 10 exposed in the second grooves 52x is the portion that becomes the second peripheral portion 10t after singulation. The first grooves 51x and the second grooves 52x may be formed, for example, by irradiating the first laminate 51 and the second laminate 52 with a laser beam having an absorptive wavelength. In the case of irradiation with the laser beam, the widths of the first grooves 51x and the second grooves 52x increase with the distance from the core layer 10, for example. Further, by adjusting the irradiation area of the laser beam for forming the first grooves 51x and the second grooves 52x, the corners of the first laminate 51 and the second laminate 52 are each effectively formed into a curved shape, as illustrated by dashed-line circles in FIG. 6. Forming the corners of the first laminate 51 and the second laminate 52 in curved shapes effectively prevents the cracking of the insulating layers at these corners. The first grooves 51x and the second grooves 52x may alternatively be formed by using a cutting blade.

After the first grooves 51x and the second grooves 52x are formed, the first surface 10a of the core layer 10 exposed in the first grooves 51x is irradiated with a laser beam L along the cutting regions D. By condensing the laser beam inside the core layer 10, a modified layer serving as a starting point for division is formed inside the core layer 10 at the positions located under the cutting regions D. In this step, the core layer 10 is irradiated with a laser beam having a transmissive wavelength.

In the step illustrated in FIG. 5B, the core layer 10 is cut along the cutting regions D illustrated in FIG. 5A to produce a plurality of singulated structures 1S. By cutting along the cutting regions D, the first grooves 51x are each divided, and in each structure 1S, the first surface 10a of the core layer 10 that was originally exposed in the first grooves 51x becomes the first peripheral portion 10s. Further, the second grooves 52x are each divided, and in each structure 1S, the second surface 10b of the core layer 10 that was originally exposed in the second grooves 52x becomes the second peripheral portion 10t. That is, in each structure 1S, the first peripheral portion 10s of the first surface 10a of the core layer 10 is exposed outside the first laminate 51, and the second peripheral portion 10t of the second surface 10b of the core layer 10 is exposed outside the second laminate 52.

The cutting may be performed, for example, by attaching the structure illustrated in FIG. 5A to an expansion tape and stretching the tape radially outward with respect to the structure. Stretching the tape causes forces to be applied to the modified portions of the core layer 10 in the radially outward direction in which the tape expands. As a result, the core layer 10 is divided along the modified layer serving as the starting point of separation.

Instead of the method of using the expansion tape, for example, a roller or a rod-shaped pressing member may be used to apply a force around the cutting regions D to divide the core layer 10.

In the step illustrated in FIG. 5C, a resin portion 41 is formed on each of the singulated structures 1S illustrated in FIG. 5B. Through this process, the manufacture of the interconnect substrate 1 is completed. The resin portion 41 is formed by using an insulating resin containing no filler so as to cover the side surface 10c of the core layer 10, the part of the first peripheral portion 10s adjacent to the side surface 10c of the core layer 10, and the part of the second peripheral portion 10t adjacent to the side surface 10c of the core layer 10. The first end surface 41a of the resin portion 41 is spaced apart from the side surface 51c of the first laminate 51, and the second end surface 41b of the resin portion 41 is spaced apart from the side surface 52c of the second laminate 52. Although the resin portion 41 may be formed by any method in the step of forming the resin portion 41, an example of a preferred forming method will be described with reference to FIGS. 7A through 7C.

First, as illustrated in FIG. 7A, a chamber 300A is prepared, and the first laminate 51 is held by bringing the rim of the chamber 300A in contact with the part of the first peripheral portion 10s adjacent to the side surfaces 51c of the first laminate 51. This arrangement effectively forms a sealed space S1 between the inner wall surface of the chamber 300A and the first surface 51a of the first laminate 51. The sealed space S1 may be evacuated and depressurized by the depressurizing device 310. This enables the chamber 300A to stably hold the first laminate 51. In FIGS. 7A to 7C, arrows indicate the direction in which air is withdrawn by the depressurizing device 310.

The chamber 300A preferably has a sealing material 320 of a closed-loop shape in plan view that is in contact with the inner wall surface. The sealing material 320 may have a sufficient flexibility to achieve a sealing function. Examples of the flexible material include silicone rubber and soft urethane.

When the chamber 300A holds the first laminate 51, the sealing material 320 is positioned to contact the full perimeter of the first surface 51a of the first laminate 51 in plan view. Preferably, the outer wall surface of the rim of the chamber 300A has a protrusion 330 projecting away from the side surface 51c in a closed-loop shape in plan view. Providing the protrusion 330 restricts resin flow to the outside in the direction parallel to the side surface 51c of the first laminate 51 during a subsequent process of applying a liquid resin.

Similarly, a chamber 300B is prepared, and the second laminate 52 is held by bringing the rim of the chamber 300B in contact with the part of the second peripheral portion 10t adjacent to the side surface 52c of the second laminate 52. This arrangement effectively forms a sealed space S2 between the inner wall surface of the chamber 300B and the second surface 52a of the second laminate 52. The sealed space S2 may be evacuated and depressurized by the depressurizing device 310. This enables the chamber 300B to stably hold the second laminate 52.

The chamber 300B preferably has a sealing material 320 of a closed-loop shape in plan view that is in contact with the inner wall surface. When the chamber 300B holds the second laminate 52, the sealing material 320 is positioned to contact the full perimeter of the second surface 52a of the second laminate 52 in plan view. Preferably, the outer wall surface of the rim of the chamber 300B has a protrusion 330 projecting away from the side surface 52c in a closed-loop shape in plan view. Providing the protrusion 330 restricts resin flow to the outside in the direction parallel to the side surface 52c of the second laminate 52 during a subsequent process of applying a liquid resin.

As illustrated in FIG. 7B, with the first surface 51a of the first laminate 51 and the second surface 52a of the second laminate 52 arranged parallel to the vertical direction, the structure 1S is placed on a roller 400 impregnated with liquid resin. The roller 400 is rotatable around the rotation axis 410. Here, the vertical direction refers to the direction of gravity. As an example, a sponge or porous roller 400 made of a resin such as urethane may be used as the roller 400. The roller 400 may be a tubular cylinder or a solid cylinder.

Next, as illustrated in FIG. 7C, a liquid resin is applied to the side surface 10c of the core layer 10, the part of the first peripheral portion 10s not in contact with the rim of the chamber 300A, and the part of the second peripheral portion 10t not in contact with the rim of the chamber 300B. The applied liquid resin is then cured to form the resin portion 41.

For example, while the roller 400 is rotated around the rotation axis 410, the structure 1S is rotated around a horizontal axis so that the side surface 10c and the like of the core layer 10 exposed outside the chambers 300A and 300B of the structure 1S are continuously brought into contact with the roller 400. Since the roller 400 made of sponge or the like has flexibility and elasticity, the roller surface sufficiently conforms to the shapes of the individual side surfaces of the structure 1S, enabling effective resin application. This effectively applies the liquid resin to the side surfaces 10c and the like of the core layer 10 of the structure 1S exposed outside the chambers 300A and 300B. Thereafter, the liquid resin is cured by exposure or heating to form the resin portion 41.

### Second Embodiment

The second embodiment is directed to an example of a semiconductor device in which a semiconductor chip is mounted on the interconnect substrate according to the first embodiment. In connection with the second embodiment, descriptions of the same components as those of the already described embodiment may be omitted.

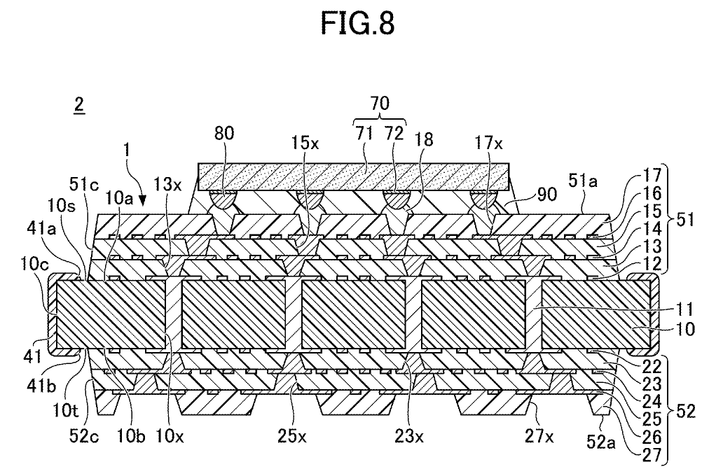

FIG. 8 is a cross-sectional view illustrating an example of a semiconductor device according to the second embodiment. Referring to FIG. 8, a semiconductor device 2 includes the interconnect substrate 1 illustrated in FIGS. 1 and 2A and 2B , a semiconductor chip 70, bumps 80, and an underfill resin 90.

The semiconductor chip 70 includes a chip 71 and electrodes 72. The chip 71 is configured such that a semiconductor integrated circuit (not illustrated) or the like is formed on a thin semiconductor substrate (not illustrated) made of, for example, silicon. The electrodes 72 electrically connected to the semiconductor integrated circuit are formed on the semiconductor substrate (not illustrated).

The bumps 80 are formed on the electrodes 72 of the semiconductor chip 70, and electrically connects the electrodes 72 and the external connection terminals 18 of the interconnect substrate 1. The electrodes 72 may be formed of, for example, copper. The bumps 80 are, for example, solder bumps. The material of the solder bumps may be, for example, an alloy containing Pb, an alloy of Sn and Cu, an alloy of Sn and Ag, an alloy of Sn, Ag and Cu, or the like. The underfill resin 90 fills a gap between the semiconductor chip 70 and the upper surface of the solder resist layer 17 of the interconnect substrate 1. The underfill resin 90 may be formed, for example, by pouring a liquid resin from one or more ends of the first surface 51a into the gap between the semiconductor chip 70 and the upper surface of the solder resist layer 17 of the interconnect substrate 1, followed by curing the liquid resin.

In this manner, the fabrication of a semiconductor device is effectively achieved by mounting the semiconductor chip on the interconnect substrate according to the first embodiment.

According to at least one embodiment, an interconnect substrate having a core layer made of glass is provided in which the breakage of the side surface of the core layer is reduced.

Although the preferred embodiments have been described in detail, the present invention is not limited to these embodiments, and various modifications and substitutions may be made to the above-described embodiments without departing from the scope of the appended claims.

For example, the above-described embodiments are directed to the interconnect substrate that has the first laminate on the first surface of the core layer made of glass and the second laminate on the second surface. However, the present invention may be applied to an interconnect substrate having the first laminate on the first surface of the core layer made of glass and not having the second laminate on the second surface, while providing substantially the same advantageous effects. In the case where the interconnect substrate does not have the second laminate, the through holes may not be provided in the core layer.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

The present disclosures non-exhaustively include the subject matter set out in the following clauses.

Clause 1. A method of making an interconnect substrate, comprising:
providing a core layer made of glass having a plurality of interconnect regions for singulation into interconnect substrates and cutting regions along which cuts are to be made for the singulation;
forming a first laminate including an interconnect layer and an insulating layer on one surface of the core layer;
forming first grooves penetrating the first laminate and exposing the one surface of the core layer, each of the first grooves extending along and straddling a corresponding one of the cutting regions;
cutting the core layer along the cutting regions to produce a plurality of singulated structures;and
forming a resin portion after the cutting,
wherein the insulating layer contains a filler, and the resin portion has a filler content smaller than that of the insulating layer or does not contain a filler,
wherein in the cutting of the core layer, each of the singulated structures is such that a first peripheral portion of the one surface of the core layer is not covered with the first laminate, and
wherein the forming of the resin portion forms the resin portion covering a side surface of the core layer and a part of the first peripheral portion adjacent to the side surface of the core layer, such that a first end surface of the resin portion located toward the first laminate is spaced apart from a side surface of the first laminate.

Clause 2. The method according to clause 1, wherein the forming of the resin portion includes:
arranging a chamber such that a rim of the chamber is brought in contact with a part of the first peripheral portion located toward the side surface of the first laminate, thereby holding the first laminate; and
applying, after the arranging the chamber, a liquid resin to the side surface of the core layer and the first peripheral portion not in contact with the rim, followed by curing the liquid resin to form the resin portion.

Clause 3. The method according to clause 2, wherein the forming of the resin portion includes applying the liquid resin with a roller.

Clause 4. The method according to clause 1, further comprising:
prior to the cutting of the core layer,
forming a second laminate including an interconnect layer and an insulating layer on another surface of the core layer; and
forming second grooves penetrating the second laminate and exposing the another surface of the core layer, each of the second grooves extending along and straddling a corresponding one of the cutting regions,
wherein in the cutting of the core layer, each of the singulated structures is such that a second peripheral portion of the another surface of the core layer is not covered with the second laminate, and
wherein the forming of the resin portion forms the resin portion further covering a part of the second peripheral portion adjacent to the side surface of the core layer, such that a second end surface of the resin portion located toward the second laminate is spaced apart from a side surface of the second laminate.

What is claimed is:

1. An interconnect substrate comprising:
a core layer made of glass having one surface and another surface;
a first laminate including an interconnect layer and an insulating layer and disposed on the one surface of the core layer; and
a resin portion,
wherein the insulating layer contains a filler, and the resin portion has a filler content smaller than that of the insulating layer or does not contain a filler,
wherein a first peripheral portion of the one surface of the core layer is not covered with the first laminate,
wherein the resin portion covers a side surface of the core layer and a part of the first peripheral portion, the part being adjacent to the side surface of the core layer, and
wherein a first end surface of the resin portion located toward the first laminate is spaced apart from a side surface of the first laminate.

2. The interconnect substrate according to claim 1, wherein in plan view, an inner peripheral area of the first peripheral portion is exposed in a frame shape between the first laminate and the resin portion.

3. The interconnect substrate according to claim 1, wherein the insulating layer includes a thermosetting resin, and the resin portion includes a thermoplastic resin.

4. The interconnect substrate according to claim 1, wherein a side surface of the first laminate and the first end surface of the resin portion are each inclined at an oblique angle relative to the one surface of the core layer, and
wherein the side surface of the first laminate and the first end surface of the resin portion are inclined such that a gap therebetween increases with distance from the one surface of the core layer.

5. The interconnect substrate according to claim 1, further comprising a second laminate including an interconnect layer and an insulating layer and disposed on the another surface of the core layer,
wherein a second peripheral portion of the another surface of the core layer is not covered with the second laminate,
wherein the resin portion further covers a part of the second peripheral portion that is adjacent to the side surface of the core layer, and
wherein a second end surface of the resin portion located toward the second laminate is spaced apart from a side surface of the second laminate.

6. The interconnect substrate according to claim 5, wherein a side surface of the second laminate and the second end surface of the resin portion are each inclined at an oblique angle relative to the another surface of the core layer, and
wherein the side surface of the second laminate and the second end surface of the resin portion are inclined such that a gap therebetween increases with distance from the another surface of the core layer.
